(19) United States
(12) Patent Application Publication
(10) Pub. No.: US 2025/0220956 A1
(43) Pub. Date: Jul. 3, 2025

(54) THIN FILM TRANSISTOR AND DISPLAY APPARATUS COMPRISING THE SAME

(71) Applicant: LG Display Co., Ltd., Seoul (KR)

(72) Inventors: JuHeyuck BAECK, Paju-si (KR); Younghyun KO, Paju-si (KR)

(21) Appl. No.: 18/946,672

(22) Filed: Nov. 13, 2024

(30) Foreign Application Priority Data
Dec. 27, 2023 (KR) 10-2023-0192588

(51) Int. Cl. H01L 29/786; H01L 29/10; H01L 29/24; H10K 59/121

(52) U.S. Cl. CPC H10D 30/6704; H10D 30/6755; H10D 30/751; H10D 62/80; H10K 59/1213

(57) ABSTRACT

A thin film transistor and a display apparatus including the thin film transistor are provided. The thin film transistor includes an active layer on a substrate and a gate electrode that is spaced apart from the active layer and overlaps at least a part of the active layer, wherein the active layer includes a main active layer and a carrier control contacting the main active layer, and wherein the carrier control layer includes an oxide semiconductor material and an element of group 15 of periodic table.

### CROSS-REFERENCE TO RELATED APPLICATIONS

This application claims the benefit and priority of the Korean Patent Application No. 10-2023-0192588 filed on Dec. 27, 2023, which is hereby incorporated by reference, for all purposes, as if fully set forth herein.

### BACKGROUND

### Technical Field

The present disclosure relates to a thin film transistor and a display apparatus including the thin film transistor.

### Description of the Related Art

Transistor is widely used as a switching device or a driving device in the electronic field. In particular, since a thin film transistor can be manufactured on a glass or a plastic substrate, it is widely used as a switching element in display apparatus such as a liquid crystal display apparatus or an organic light emitting device.

Based on the material constituting the active material layer, the thin film transistors may be classified as an amorphous silicon thin film transistor in which amorphous silicon is used as the active material layer, a polycrystalline silicon thin film transistor in which polycrystalline silicon is used as the active material layer, and an oxide semiconductor thin film transistor in which oxide semiconductor used as the active material layer.

Among these, an oxide semiconductor thin film transistor (oxide semiconductor TFT), which has a high mobility and can have large resistance changes depending on the oxygen content, has an advantage in that desired properties may easily be obtained. In addition, the manufacturing cost of an oxide semiconductor thin film transistor is low because the oxide constituting the active layer can be formed at a relatively low temperature during the manufacturing process of the oxide semiconductor thin film transistor. Due to the nature of oxide, oxide semiconductor is transparent, thus the oxide semiconductor thin film transistor is advantageous for embodying a transparent display apparatus.

There are many uses for oxide semiconductor thin film transistors, and oxide semiconductor thin film transistors can be used in a variety of environments. However, the reliability of oxide semiconductor thin film transistors may decrease in an environment of high temperature.

### BRIEF SUMMARY

An aspect of the present disclosure is to provide a thin film transistor with excellent stability and reliability.

An aspect of the present disclosure is to provide a thin film transistor capable of suppressing changes in threshold voltage (Vth) caused by variation in the Fermi energy (Ef) level of the oxide semiconductor layer at high temperature. An aspect of the present disclosure is to provide a thin film transistor that has a carrier control layer and has a small change in threshold voltage (Vth) even when driven at high temperature.

An aspect of the present disclosure is to provide a thin film transistor including a carrier control layer capable of trapping excited electrons in a channel portion. An aspect of the present disclosure is to provide a thin film transistor that can secure temperature stability of the Fermi energy (Ef) level by having a carrier control layer that can trap carriers with high temperature variability.

An aspect of the present disclosure is to provide a thin film transistor with excellent driving stability and reliability by reducing the variation of the Fermi energy (Ef) level with temperature by the carrier control layer.

An aspect of the present disclosure is to provide a display apparatus including the thin film transistor as described above, and has excellent reliability.

In accordance with an aspect of the present disclosure, the above and other objects can be accomplished by the provision of a thin film transistor including an active layer on a substrate and a gate electrode that is spaced apart from the active layer and overlaps at least a portion of the active layer, wherein the active layer includes a main active layer comprising an oxide semiconductor layer and a carrier control layer contacting the main active layer, wherein the carrier control layer includes an oxide semiconductor material and an element of group 15 of periodic table.

The element of group 15 of periodic table may include at least one of phosphorus (P), arsenic (As), antimony (Sb), and bismuth (Bi).

The oxide semiconductor material may include at least one of an IGZO (InGaZnO)-based, an IGZTO (InGaZnSnO)-based, an IZO (InZnO)-based, an IGO (InGaO)-based, an ITO (InSnO)-based, an ITZO (InSnZnO)-based, an InO (InO)-based, a ZnO-based, an IWZO (InWZnO)-based, and a FIZO (FeInZnO)-based oxide semiconductor material.

The carrier control layer may have a thickness ranging from 1 to 5 nm.

The concentration of the element of group 15 of periodic table may be adjusted to a range from 1×10¹⁵/cm³ to 1×10¹⁷/cm³ in the carrier control layer.

The carrier control layer may trap excited electrons.

The carrier control layer may have a thickness smaller than a thickness of the main active layer, and may be disposed closer to the gate electrode than the main active layer.

The carrier control layer may have a thickness smaller than a thickness of the main active layer, and may be disposed farther from the gate electrode than the main active layer.

The carrier control layer may include a first carrier control layer and a second carrier control layer. The first carrier control layer and the second carrier control layer each may have a thickness smaller than a thickness of the main active layer, and the main active layer may be disposed between the first carrier control layer and the second carrier control layer.

The main active layer may include a first oxide semiconductor layer and a second oxide semiconductor layer on the first oxide semiconductor layer. The second oxide semiconductor layer may have a higher carrier concentration than a carrier concentration of the first oxide semiconductor layer and may be in contact with the carrier control layer.

The active layer may include a channel portion overlapping the gate electrode, a source connection portion connected to one side of the channel portion, and a drain connection portion connected to the other side of the channel portion. The source connection portion and the drain connection portion provided in the carrier control layer may include an element of group 15 of periodic table and at least one of boron (B), fluorine (F), and hydrogen (H).

The active layer may be disposed between the substrate and the gate electrode.

The gate electrode may be disposed between the substrate and the active layer.

An embodiment of the present disclosure provides a display apparatus including the thin film transistor and a light emitting element.

According to an embodiment of the present disclosure, a carrier control layer containing an element of group 15 of periodic table can trap excited electrons of the channel portion. In addition, carriers with high volatility or variation with a change of temperature may be trapped to the carrier control layer. As a result, in the semiconductor layer or in the channel portion, temperature stability at the Fermi energy (Ef) level can be secured, and the stability and reliability of the thin film transistor can be improved.

According to an embodiment of the present disclosure, since the carrier control layer can trap carriers having high volatility with high temperature, temperature stability of the Fermi energy (Ef) level in the thin film transistor can be secured.

A thin film transistor according to an embodiment of the present disclosure may have excellent driving stability and reliability. A display apparatus according to another embodiment of the present disclosure including the thin film transistor as described above may have excellent reliability.

In addition to the effects mentioned above, other features and advantages of the present disclosure are described below. From the description and explanation, the present disclosure will be clearly understandable to those skilled in the art to which the present disclosure pertains.

### BRIEF DESCRIPTION OF THE SEVERAL VIEWS OF THE DRAWINGS

The accompanying drawings, which are included to provide a further understanding of the disclosure and are incorporated in and constitute a part of this application, illustrate embodiments of the disclosure and together with the explanation serve to explain the principle of the disclosure. The above and other objects, features and other advantages of the present disclosure will be more clearly understood from the following detailed description taken in conjunction with the accompanying drawings.

FIG. 1 is a cross-sectional view of a thin film transistor according to an embodiment of the present disclosure.

FIG. 2A is a schematic diagram explaining the change in threshold voltage (Vth) of a conventional oxide semiconductor thin film transistor under a PBTS (Positive Bias Temperature Stress) condition.

FIG. 2B is a schematic diagram of the energy band of an oxide semiconductor.

FIG. 3 is a diagram illustrating a bonding state of an element of group 15 of periodic table (M15) doped in an oxide semiconductor material.

FIG. 4 is a schematic diagram explaining a change in band gap due to an element of group 15 of periodic table (M15).

FIG. 5 is a schematic band diagram of an active layer of a thin film transistor according to an embodiment of the present disclosure.

FIG. 6 is a cross-sectional view of a thin film transistor according to another embodiment of the present disclosure.

FIG. 7 is a cross-sectional view of a thin film transistor according to another embodiment of the present disclosure.

FIG. 8 is a cross-sectional view of a thin film transistor according to another embodiment of the present disclosure.

FIG. 9 is a cross-sectional view of a thin film transistor according to another embodiment of the present disclosure.

FIG. 10 is a cross-sectional view of a thin film transistor according to another embodiment of the present disclosure.

FIG. 11 is a cross-sectional view of a thin film transistor according to another embodiment of the present disclosure.

FIG. 12 shows graphs illustrating changes in threshold voltage (Vth) of thin film transistors according to an example and a comparative example under a PBTS (Positive Bias Temperature Stress) condition.

FIG. 13A to FIG. 13D are graphs of voltage-current changes of a thin film transistor according to the thickness of the carrier control layer.

FIG. 14A to FIG. 14C are voltage-current change graphs of thin film transistors according to the type of the element of group 15 of periodic table.

FIG. 15 is a graph of the change in threshold voltage (Vth) of a thin film transistor according to the concentration of the element of group 15 of periodic table, in a heated state of 100° C.

FIG. 16 is a schematic diagram of a display apparatus according to another embodiment of the present disclosure.

FIG. 17 is a circuit diagram of a pixel of FIG. 16.

FIG. 18 is a plan view of the pixel of FIG. 17.

FIG. 19 is a cross-sectional view along I-I′ of FIG. 18.

### DETAILED DESCRIPTION

Advantages and features of the present disclosure, and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete, and will fully explain the present disclosure to those skilled in the art.

A shape, a size, a ratio, an angle, and a number disclosed in the drawings for describing embodiments of the present disclosure are merely an example, and thus, the present disclosure is not limited to the illustrated details. Like reference numerals refer to like elements throughout the specification. In the following description, when the detailed description of the relevant known function or configuration is determined to unnecessarily obscure the important point of the present disclosure, the detailed description will be omitted.

In a case where ‘comprise,’ ‘have,’ and ‘include’ described in the present specification are used, another part may be added unless ‘only˜’ is used. The terms of a singular form may include plural forms unless referred to the contrary.

In construing an element, the element is construed as including an error range although there is no explicit description.

In describing a position relationship, for example, when the position relationship is described as ‘upon˜,’ ‘above˜,’ ‘below˜,’ and ‘next to˜,’ one or more other portions may be arranged between the described two portions unless ‘just’ or ‘direct’ is used.

Spatially relative terms such as “below,” “beneath,” “lower,” “above,” and “upper” may be used herein to easily describe a relationship of one element or elements to another element or elements as illustrated in the figures. It will be understood that these terms are intended to encompass different orientations of the device in addition to the orientation depicted in the figures. For example, if the device illustrated in the figure is reversed, the device described to be arranged “below,” or “beneath” another device may be arranged “above” another device. Therefore, an exemplary term “below or beneath” may include “below or beneath” and “above” orientations. Likewise, an exemplary term “above” or “on” may include “above” and “below or beneath” orientations.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc., may be used herein to describe various elements, these elements should not be limited by these terms. These terms are only used to distinguish one element from another element. For example, a first element could be termed a second element, and, similarly, a second element could be termed a first element, without departing from the scope of the present disclosure.

The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item.

Features of various embodiments of the present disclosure may be partially or overall coupled to or combined with each other, and may be variously inter-operated with each other and driven technically as those skilled in the art can sufficiently understand. The embodiments of the present disclosure may be carried out independently from each other, or may be carried out together in co-dependent relationship.

Hereinafter, a thin film transistor and a display apparatus including the same according to an embodiment of the present disclosure will be described in detail with reference to the attached drawings. In the drawings, the same or similar elements are denoted by the same reference numerals even though they are depicted in different drawings.

In the embodiments of the present disclosure, a source electrode and a drain electrode are distinguished from each other, for convenience of description. However, the source electrode and the drain electrode may be used interchangeably. The source electrode may be the drain electrode, and the drain electrode may be the source electrode. Also, the source electrode in any an embodiment of the present disclosure may be the drain electrode in another embodiment of the present disclosure, and the drain electrode in any an embodiment of the present disclosure may be the source electrode in another embodiment of the present disclosure.

In some embodiments of the present disclosure, for convenience of explanation, a source region and a source electrode are distinguished, and a drain region and a drain electrode are distinguished, but the embodiments of the present disclosure are not limited thereto. The source region may be a source electrode, and the drain region may be a drain electrode. In addition, the source region may be a drain electrode, and the drain region may be a source electrode.

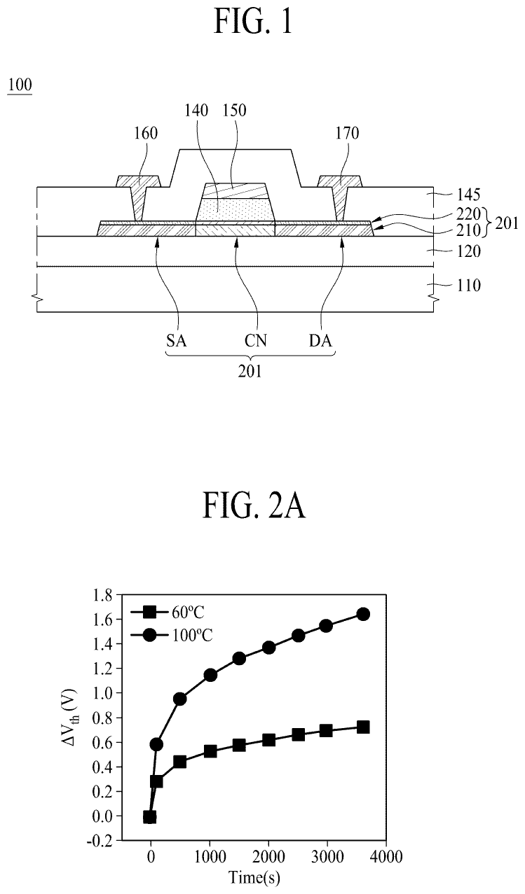

FIG. 1 is a cross-sectional view of a thin film transistor 100 according to an embodiment of the present disclosure.

Referring to FIG. 1, the thin film transistor 100 according to an embodiment of the present disclosure includes an active layer 201 on a substrate 110, and a gate electrode 150 which is spaced apart from the active layer 201 and overlaps at least a part of the active layer 201. In addition, the thin film transistor 100 may include a source electrode 160 and a drain electrode 170 that are spaced apart from each other and electrically connected to the active layer 201, respectively.

The active layer 201 includes a channel portion CN overlapping the gate electrode 150, a source connection portion SA connected to one side of the channel portion CN, and a drain connection portion DA connected to the other side of the channel portion CN.

According to an embodiment of the present disclosure, the thin film transistor 100 may be formed by the active layer 201, the gate electrode 150, the source electrode 160, and the drain electrode 170. Alternatively, the thin film transistor 100 may be said to comprise a channel portion CN, a source connection portion SA, a drain connection portion DA, and a gate electrode 150.

The thin film transistor 100 may be disposed on a substrate 110.

The substrate 110 supports other components of the thin film transistor 100. If it supports the thin film transistor 100, it can be referred to as the substrate 110 without limitation.

Glass or plastic may be used as the substrate 110. A transparent plastic with flexible properties, for example, polyimide, may be used as the plastic. When polyimide is used as the substrate 110, considering that a high temperature deposition process is performed on the substrate 110, a heat-resistant polyimide that can withstand high temperatures may be used.

A light shielding layer may be disposed on the substrate 110 (see FIG. 7). The light shielding layer may be omitted.

Referring to FIG. 1, a buffer layer 120 may be disposed on the substrate 110. The buffer layer 120 may be made of an insulating material. For example, the buffer layer 120 may include at least one insulating material selected from the group consisting of a silicon oxide, a silicon nitride, and a metal-based oxide. The buffer layer 120 may have a single-layer structure or a multi-layer structure.

The buffer layer 120 blocks air and moisture to protect channel portion CN. In addition, a surface of the upper part of the substrate 110 can be made flat by the buffer layer 120.

The active layer 201 is disposed on the substrate 110. Referring to FIG. 1, the active layer 201 may be disposed on the buffer layer 120 which is on the substrate 110.

According to an embodiment of the present disclosure, the active layer 201 may include an oxide semiconductor material. In detail, the channel portion CN, the source connection portion SA, and the drain connection portion DA may include an oxide semiconductor material.

For example, the oxide semiconductor material may include at least one of IGZO (InGaZnO)-based, IGZTO (InGaZnSnO)-based, IZO (InZnO)-based, IGO (InGaO)-based, ITO (InSnO)-based, ITZO (InSnZnO)-based, InO (InO)-based, ZnO-based, IWZO (InWZnO)-based, and FIZO (FeInZnO)-based oxide semiconductor materials. However, an embodiment of the present disclosure is not limited thereto, and the active layer 201 may include other oxide semiconductor materials conventionally known in the art.

The channel portion CN overlaps the gate electrode 150. The channel portion CN has semiconductor properties. Depending on the voltage applied to the gate electrode 150, the channel portion CN may have conductor-like electrical characteristics or insulator-like characteristics.

According to an embodiment of the present disclosure, the source connection portion SA and the drain connection portion DA may each have electrical characteristics similar to those of a conductor. For example, the source connection portion SA and drain connection portion DA may each have a resistivity of 10⁻⁴ Ω·cm or less. The source connection portion SA and the drain connection portion DA may each have a constant resistivity regardless of whether the thin film transistor 100 is turned on or turned off.

According to an embodiment of the present disclosure, the source connection portion SA and the drain connection portion DA may be referred to as a conductor area or a conductorized area.

For example, the source connection portion SA and the drain connection portion DA can be formed by selectively conductorizing the active layer 201. In detail, the source connection portion SA and the drain connection portion DA may be formed by selectively conductorizing the oxide semiconductor material constituting the active layer 201.

The selectively conductorized portion of the active layer 201 has excellent electrical conductivity and can function as a wiring portion. A portion of the active layer 201 may be selectively conductorized by a selective conductorization.

According to an embodiment of the present disclosure, selective conductorization refers to improving the conductivity of a selected portion of the active layer 201 or providing conductivity to the selected portion. According to an embodiment of the present disclosure, selective conductorization can be achieved by doping a dopant in a selected region. The source connection portion SA and the drain connection portion DA may include dopants. According to an embodiment of the present disclosure, doping can be achieved by implanting ions of a conductorizing element.

According to an embodiment of the present disclosure, the dopant may include at least one of Boron (B), Fluorine (F), and Hydrogen (H).

According to an embodiment of the present disclosure, the active layer 201 is formed of an oxide semiconductor material, and selected portions of the active layer 201 are doped with a dopant, thereby source connection portion SA and drain connection portion DA can be formed.

However, an embodiment of the present disclosure is not limited thereto, and conductivity may be provided or imparted to the source connection portion SA and the drain connection portion DA by other methods. According to an embodiment of the present disclosure, conductivity may be imparted to the source connection portion SA and the drain connection portion DA through plasma processing. For example, during the patterning process of the gate insulating layer 140 or the gate electrode 150, a selective conductorization is performed through plasma processing, as a result, the source connection portion SA and the drain connection portion DA can be formed.

According to an embodiment of the present disclosure, a region of the active layer 201 that is not doped with the dopant and is not conductorized may become the channel portion CN.

Referring to FIG. 1, based on the stacked structure, the active layer 201 may include a main active layer 210 and a carrier control layer 220 contacting the main active layer 210. The main active layer 210 and the carrier control layer 220 will be described later.

Referring to FIG. 1, a gate insulating layer 140 is disposed on the active layer 201. The gate insulating layer 140 may include at least one of silicon oxide, silicon nitride, and metal-based oxide. The gate insulating layer 140 may have a single-layer structure or a multi-layer structure. The gate insulating layer 140 protects the channel portion CN.

Referring to FIG. 1, the gate insulating layer 140 may be patterned. For example, the gate insulating layer 140 may be patterned into a shape corresponding to the gate electrode 150.

According to an embodiment of the present disclosure, during the patterning process of the gate insulating layer 140 and the gate electrode 150, selective conductorization may be performed to form a source connection portion SA and a drain connection portion DA. In detail, during the patterning process of the gate insulating layer 140 and the gate electrode 150, selective conductorization may be performed in a plasma treatment process to form the source connection portion SA and the drain connection portion DA.

However, an embodiment of the present disclosure is not limited thereto, and the gate insulating layer 140 may be formed on the entire upper surface of the substrate 110. For example, the gate insulating layer 140 may cover all of the channel portion CN, source connection portion SA, and drain connection portion DA excluding the contact area.

The gate electrode 150 is disposed on the gate insulating layer 140. The gate electrode 150 is formed to overlap the channel portion CN of the active layer 201. Referring to FIG. 1, the active layer 201 may be disposed between the substrate 110 and the gate electrode 150.

The gate electrode 150 may include at least one of an aluminum-based metal such as aluminum (Al) or an aluminum alloy, a silver-based metal such as silver (Ag) or a silver alloy, a copper-based metal such as copper (Cu) or a copper alloy, a molybdenum-based metal such as molybdenum (Mo) or molybdenum alloy, chromium (Cr), tantalum (Ta), neodymium (Nd), and titanium (Ti). The gate electrode 150 may have a multilayer structure including at least two conductive layers with different physical properties.

Referring to FIG. 1, an interlayer insulating film 145 is disposed on the gate insulating layer 140 and the gate electrode 150. The interlayer insulating film 145 is an insulating layer made of an insulating material. The interlayer insulating film 145 may be made of an organic material or an inorganic material, or may be a laminate of an organic material layer and an inorganic material layer.

A source electrode 160 and a drain electrode 170 may be disposed on the interlayer insulating film 145.

Each of the source electrode 160 and the drain electrode 170 may include at least one of molybdenum (Mo), aluminum (Al), chromium (Cr), gold (Au), titanium (Ti), nickel (Ni), neodymium (Nd), copper (Cu), and alloys thereof. Each of the source electrode 160 and the drain electrode 170 may be made of a single layer structure or a multi-layer with two or more layers formed of metal or a metal alloy.

According to an embodiment of the present disclosure, the source electrode 160 may be connected to the source connection portion SA. In detail, the source electrode 160 may be electrically connected to the source connection portion SA through a contact hole and can transmit an electric signal to the channel portion CN.

The drain electrode 170 is spaced apart from the source electrode 160 and may be connected to the drain connection portion DA. In detail, the drain electrode 170 may be electrically connected to the drain connection portion DA through a contact hole, and can transmit an electrical signal to the channel portion CN.

According to an embodiment of the present disclosure, the source connection portion SA may serve as a source electrode, and the drain connection portion DA may serve as a drain electrode. The source connection portion SA and drain connection portion DA may be interchanged each other.

The source electrode 160 and drain electrode 170 may be omitted. When the source electrode 160 and the drain electrode 170 are omitted, the source connection portion SA may become the source electrode and the drain connection portion DA may become the drain electrode.

Hereinafter, with reference to FIG. 1, the stacked structure of the active layer 201 will be described in more detail.

According to an embodiment of the present disclosure, the active layer 201 may include a main active layer 210 and a carrier control layer 220 contacting the main active layer 210.

The main active layer 210 may include an oxide semiconductor layer. According to an embodiment of the present disclosure, the main active layer 210 may be made of an oxide semiconductor layer.

For example, the oxide semiconductor layer included in the main active layer 210 may include at least one of IGZO (InGaZnO)-based, IGZTO (InGaZnSnO)-based, IZO (InZnO)-based, IGO (InGaO)-based, ITO (InSnO)-based, ITZO (InSnZnO)-based, InO (InO)-based, ZnO-based, IWZO (InWZnO)-based and FIZO (FeInZnO)-based oxide semiconductor material.

The main active layer 210 includes a channel portion CN overlapping the gate electrode 150, a source connection portion SA connected to one side of the channel portion CN, and a drain connection portion DA connected to the other side of the channel portion CN. When the source connection portion SA and the drain connection portion DA have been conductorized by dopant doping, the source connection portion SA and the drain connection portion DA of the main active layer 210 may include at least one of Boron (B), Fluorine (F), and Hydrogen (H), respectively.

The carrier control layer 220 may include an oxide semiconductor material and an element of group 15 of periodic table. The carrier control layer 220 may be referred to have a structure in which an oxide semiconductor material is doped with an element of group 15 of periodic table. In detail, carrier control layer 220 may have a structure in which a layer made of an oxide semiconductor material is doped with an element of group 15 of periodic table.

According to an embodiment of the present disclosure, the carrier control layer 220 may has a thickness smaller than a thickness of the main active layer 210. In addition, referring to FIG. 1, the carrier control layer 220 may be disposed closer to the gate electrode 150 than the main active layer 210. Referring to FIG. 1, the main active layer 210 may be disposed farther from the gate electrode 150 than the carrier control layer 220. More specifically, the main active layer 210, the carrier control layer 220, the gate insulator 140, and the gate electrode 150 may be sequentially disposed. However, an embodiment of the present disclosure is not limited thereto, and the main active layer 210 may be disposed closer to the gate electrode 150 than the carrier control layer 220.

The carrier control layer 220 may include a channel portion CN overlapping the gate electrode 150, a source connection portion SA connected to one side of the channel portion CN, and a drain connection portion DA connected to the other side of the channel portion CN.

When the source connection portion SA and the drain connection portion DA are conductorized by dopant doping, each of the source connection portion SA and drain connection portion DA provided in the carrier control layer 220 may include an element of group 15 of periodic table, and include at least one of Boron (B), Fluorine (F), and Hydrogen (H).

According to an embodiment of the present disclosure, the carrier control layer 220 may include an oxide semiconductor layer and an element of group 15 of periodic table doped into the oxide semiconductor layer.

The oxide semiconductor material included in the carrier control layer 220 may include at least one of IGZO (InGaZnO)-based, IGZTO (InGaZnSnO)-based, IZO (InZnO)-based, IGO (InGaO)-based, ITO (InSnO)-based, ITZO (InSnZnO)-based, InO (InO)-based, ZnO-based, IWZO (InWZnO)-based and FIZO (FeInZnO)-based oxide semiconductor material.

The element of group 15 of periodic table may include at least one of phosphorus (P), arsenic (As), antimony (Sb), and bismuth (Bi).

According to an embodiment of the present disclosure, the carrier control layer 220 containing an oxide semiconductor material and an element of group 15 of periodic table may generate an electron state to trap carriers. Herein, the carrier may be an electron.

In detail, carrier control layer 220 can form a gap state and trap excited electrons of the channel portion. Therefore, carrier control layer 220 can trap an excited electron, which is a carrier having high variation and fluidity with temperature. By trapping carriers having high variation and fluidity with temperature, the Fermi energy (Ef) level of the thin film transistor 100 can remain stable despite temperature changes. In an embodiment of the present disclosure, a carrier having high variation and fluidity with temperature refers to an electron whose trapped state has a high volatility depending on temperature changes.

In general, oxide semiconductor thin film transistors are known to have reduced reliability at high temperatures. Oxide semiconductors generally have an amorphous structure, and so local non-uniformity may occur. And thus, it is known that when the oxide semiconductor is influenced by hydrogen, etc., non-uniformity may occur in the Fermi energy (Ef) level of the oxide semiconductor. When the oxide semiconductor thin film transistor is exposed to a high temperature environment, non-uniformity may occur in the Fermi energy (Ef) level, and as a result, reliability of the oxide semiconductor thin film transistor may be reduced at high temperatures.

For this reason, depending on the usage environment of the device including the oxide semiconductor thin film transistor, changes in the current of the oxide semiconductor thin film transistor may occur and changes in the amount of electron traps may occur. This phenomenon may occur significantly in a high-temperature environment.

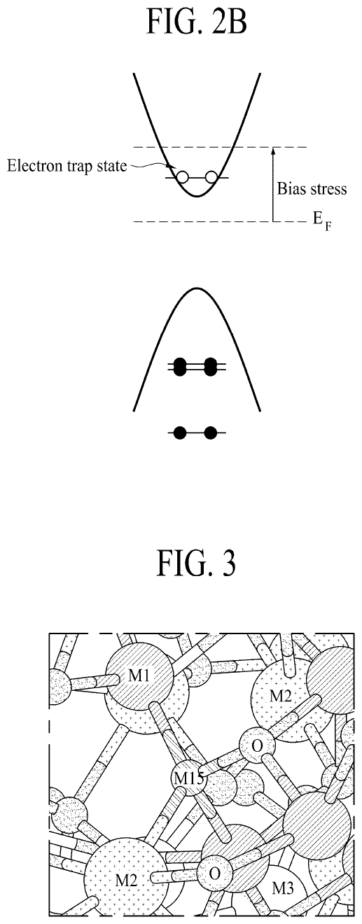

FIG. 2A is a schematic diagram explaining the change in threshold voltage (Vth) of a conventional oxide semiconductor thin film transistor under a PBTS (Positive Bias Temperature Stress) condition.

Referring to FIG. 2A, when a high temperature stress of 100° C. is applied, the change (ΔVth) in the threshold voltage (Vth) according to time (seconds, s) is greater than when a temperature stress of 60° C. is applied.

FIG. 2B is a schematic diagram of the energy band of an oxide semiconductor.

The electron trap state of an oxide semiconductor exists in the conduction band, and it is known that an electron trap occurs when bias stress is applied to the oxide semiconductor. In this case, there is no electron trap in the initial state, so it is understood that the threshold voltage (Vth) of the device changes or deteriorates when stress (e.g., voltage) is applied.

According to an embodiment of the present disclosure, in order to prevent or reduce the change (ΔVth) of threshold voltage (Vth), a carrier control layer 220 containing an element of group 15 of periodic table is disposed on the main active layer 210 including an oxide semiconductor layer.

FIG. 3 is a diagram illustrating a bonding state of an element of group 15 of periodic table (M15) doped in an oxide semiconductor material. In FIG. 3, the oxide semiconductor material is included in the carrier control layer 220.

Referring to FIG. 3, in the carrier control layer 220, the element of group 15 of periodic table (M15) doped into the oxide semiconductor material can form a bond with other metal atoms (M1, M2, M3) and oxygen atoms (O). And, a gap state may be formed in the band gap of the oxide semiconductor by the element of group 15 of periodic table (M15) which is included in the carrier control layer 220.

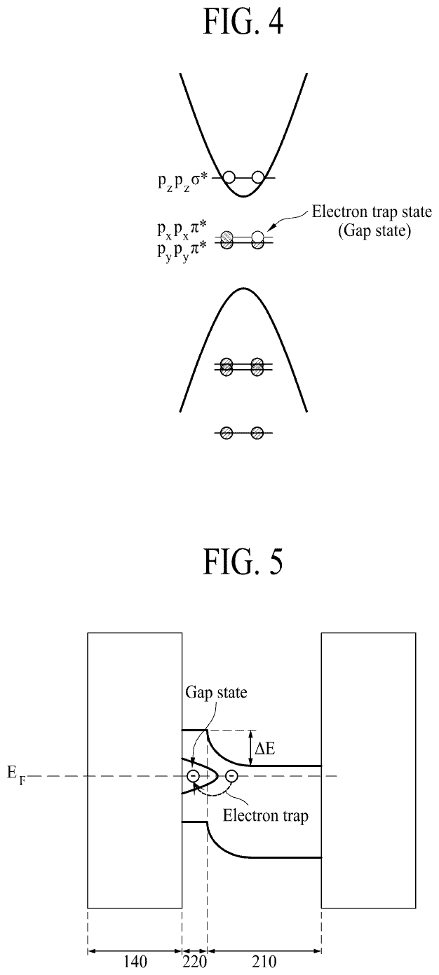

FIG. 4 is a schematic diagram explaining the change in band gap due to an element of group 15 of periodic table (M15).

Referring to FIG. 4, a gap state may be formed in the band gap of the oxide semiconductor due to the element of group 15 of periodic table (M15). The gap state formed in the band gap can serve as an electron trap state. Accordingly, excited electrons of the channel portion can be trapped in the gap state.

FIG. 5 is a schematic band diagram of the active layer 201 of the thin film transistor 100 according to an embodiment of the present disclosure.

According to an embodiment of the present disclosure, the carrier control layer 220 may be disposed in contact with the main active layer 210. A gap state is formed in the carrier control layer 220 including an oxide semiconductor material due to the element of group 15 of periodic table (M15), and an electron trap can be accomplished by the gap state. In detail, the gap state formed in the carrier control layer 220 can trap the excited electrons of the main active layer 210. In particular, the gap state formed in the carrier control layer 220 can trap the excited electrons of the channel portion.

Excited electrons in the channel portion are highly temperature-dependent and correspond to carriers that degrade the stability of the Fermi energy (Ef) level of the channel portion. According to one embodiment of the present disclosure, the carrier control layer 220 can trap the excited electrons. As a result, the instability of the Fermi energy (Ef) level of the thin film transistor 100 with temperature changes can be eliminated, and the driving stability of the thin film transistor 100 can be ensured.

Therefore, the thin film transistor according to an embodiment of the present disclosure can have excellent driving stability, and changes in threshold voltage can be reduced even in a high temperature environment. As described, the thin film transistor according to an embodiment of the present disclosure can have excellent driving stability, especially in environments where temperature changes.

According to an embodiment of the present disclosure, the carrier control layer 220 may have a thickness ranging from 1 to 5 nm. If the thickness of the carrier control layer 220 is less than 1 nm, the gap state generation effect by the carrier control layer 220 is small, and the effect of securing the driving stability of the thin film transistor 100 under high temperature stress conditions will not be significant. On the other hand, when the thickness of the carrier control layer 220 exceeds 5 nm, electrons other than excited electrons in the initial state are trapped due to an increase in the gap state, thereby reducing carriers, resultingly mobility and current of the thin film transistor may be reduced. According to an embodiment of the present disclosure, a thickness of the carrier control layer 220 is smaller than a thickness of the main active layer 210.

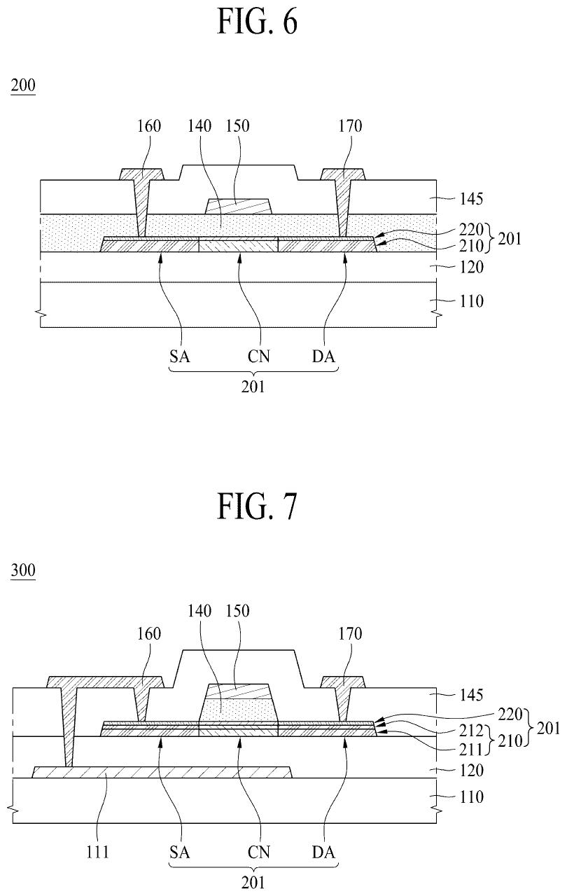

FIG. 6 is a cross-sectional view of a thin film transistor 200 according to another embodiment of the present disclosure. Hereinafter, in order to avoid redundant description, components that have already been described will be briefly described, or descriptions of components that have already been described will be omitted.

Referring to FIG. 6, the gate insulating layer 140 may be disposed on the entire upper surface of the substrate 110 without patterning. The gate insulating layer 140 may cover all of the channel portion CN, source connection portion SA, and drain connection portion DA, except the contact area.

FIG. 7 is a cross-sectional view of a thin film transistor 300 according to another embodiment of the present disclosure.

Referring to FIG. 7, the main active layer 210 may have a multi-layer structure.

According to another embodiment of the present disclosure, the main active layer 210 may include a first oxide semiconductor layer 211 and a second oxide semiconductor layer 212 on the first oxide semiconductor layer 211. In detail, the main active layer 210 may include an oxide semiconductor layer, and the oxide semiconductor layer of the main active layer 210 may include a first oxide semiconductor layer 211 and a second oxide semiconductor layer 212.

The first oxide semiconductor layer 211 supports the second oxide semiconductor layer 212. Therefore, the first oxide semiconductor layer 211 may be referred to as a support layer. According to an embodiment of the present disclosure, the second oxide semiconductor layer 212 may have a higher carrier concentration than the first oxide semiconductor layer 211 and may be in contact with the carrier control layer 220. The main channel may be formed in the second oxide semiconductor layer 212. According to an embodiment of the present disclosure, when the main active layer 210 has a multi-layer structure, the layer serving as the main channel may contact the carrier control layer 220.

Meanwhile, another embodiment of the present disclosure is not limited to the structure of FIG. 7, and the main channel may be formed in the first oxide semiconductor layer 211. In this case, the first oxide semiconductor layer 211 may have a higher carrier concentration than the second oxide semiconductor layer 212 and may contact the carrier control layer 220.

The thin film transistor 300 according to another embodiment of the present disclosure may further include a light shielding layer 111 that overlaps the channel portion CN.

The light shielding layer 111 is disposed between the substrate 110 and the active layer 201. In detail, the light shielding layer 111 may be disposed between the substrate 110 and the buffer layer 120.

The light shielding layer 111 blocks light incident from the outside to protect the channel portion CN. The light shielding layer 111 can be made of a material with light blocking properties. The light shielding layer 111 may include at least one of aluminum-based metal such as aluminum (Al) or aluminum alloys, molybdenum-based metal such as molybdenum (Mo) or molybdenum alloys, chromium (Cr), tantalum (Ta), neodymium (Nd), titanium (Ti), and iron (Fc).

According to an embodiment of the present disclosure, the light shielding layer 111 may have electric conductivity. The light shielding layer 111 may be electrically connected to either the source electrode 160 or the drain electrode 170.

Referring to FIG. 7, the light shielding layer 111 is connected to the source electrode 160, and thus may be electrically connected to the source connection portion SA. The light shielding layer 111 may directly contact the source connection portion SA. However, another embodiment of the present disclosure is not limited thereto, and the light shielding layer 111 may contact the drain connection portion DA or may be connected to the drain electrode 170.

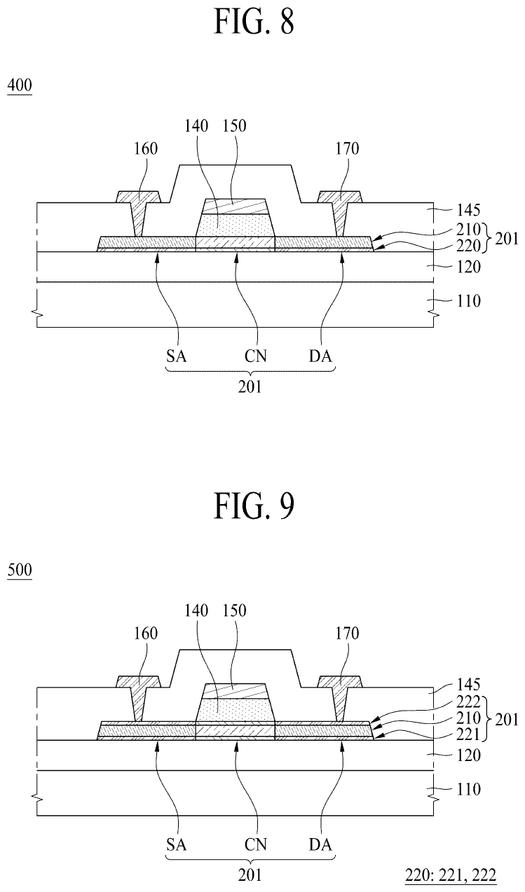

FIG. 8 is a cross-sectional view of a thin film transistor 400 according to another embodiment of the present disclosure.

According to another embodiment of the present disclosure, the carrier control layer 220 may be disposed farther from the gate electrode 150 than the main active layer 210. Referring to FIG. 8, among the main active layer 210 and the carrier control layer 220, the main active layer 210 may be disposed closer to the gate electrode 150 than the carrier control layer 220. In detail, the carrier control layer 220 may have a smaller thickness than the main active layer 210 and may be disposed further from the gate electrode 150 than the main active layer 210.

FIG. 9 is a cross-sectional view of a thin film transistor 500 according to another embodiment of the present disclosure. Referring to FIG. 9, carrier control layers 221 and 222 may be disposed on both sides of the main active layer 210.

In detail, according to another embodiment of the present disclosure, the carrier control layer 220 includes a first carrier control layer 221 and a second carrier control layer 222, and the main active layer 210 may be disposed between the first carrier control layer 221 and the second carrier control layer 222. According to another embodiment of the present disclosure, each of the first carrier control layer 221 and the second carrier control layer 222 has a thickness smaller than a thickness of the main active layer 210, and the main active layer 210 may be disposed between the first carrier control layer 221 and the second carrier control layer 222.

In the thin film transistor 500 of FIG. 9, gap states may be formed on both sides of the channel portion CN of the main active layer 210, and the excited electrons can be trapped in both sides of the main active layer 210 by the gap states.

FIGS. 1, 6, 7, 8, and 9 illustrate thin film transistors 100, 200, 300, 400, and 500 of a top gate structure in which a gate electrode 150 is disposed on the top of the active layer 201. However, embodiments of the present disclosure are not limited thereto, and the thin film transistor may have a double gate structure or a bottom gate structure.

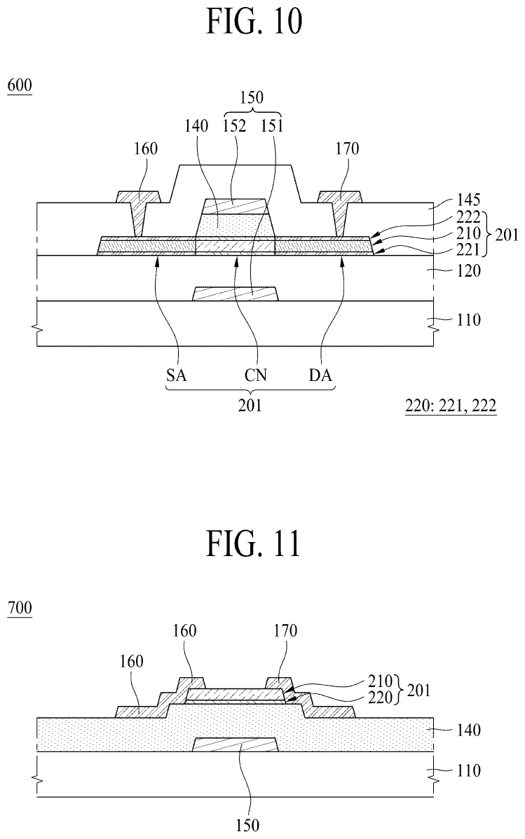

FIG. 10 is a cross-sectional view of a thin film transistor 600 according to another embodiment of the present disclosure.

Referring to FIG. 10, the thin film transistor 600 according to another embodiment of the present disclosure may have a double gate structure. In detail, the thin film transistor 600 may include gate electrodes 151 and 152 disposed on both sides of the active layer 201.

According to another embodiment of the present disclosure, the gate electrode 150 may include a first gate electrode 151 and a second gate electrode 152. The first gate electrode 151 is disposed between the substrate 110 and the active layer 201. The second gate electrode 152 is disposed on opposite sides of the first gate electrode 151 centered on the active layer 201. As a result, the active layer 201 may be disposed between the first gate electrode 151 and the second gate electrode 152.

FIG. 11 is a cross-sectional view of a thin film transistor 700 according to another embodiment of the present disclosure.

According to another embodiment of the present disclosure, a gate electrode 150 is disposed on a substrate 110, an active layer 201 is disposed on the gate electrode 150, and a source electrode 160 and a drain electrode 170 are respectively disposed on the active layer 201. A gate insulating layer 140 is disposed between the gate electrode 150 and the active layer 201. The active layer 201 includes a main active layer 210 and a carrier control layer 220 in contact with the main active layer 210.

Referring to FIG. 11, the gate electrode 150 is disposed between the substrate 110 and the active layer 201. As shown in FIG. 11, the structure of the thin film transistor 700 in which the gate electrode 150 is disposed below the active layer 201 is called as a bottom gate structure.

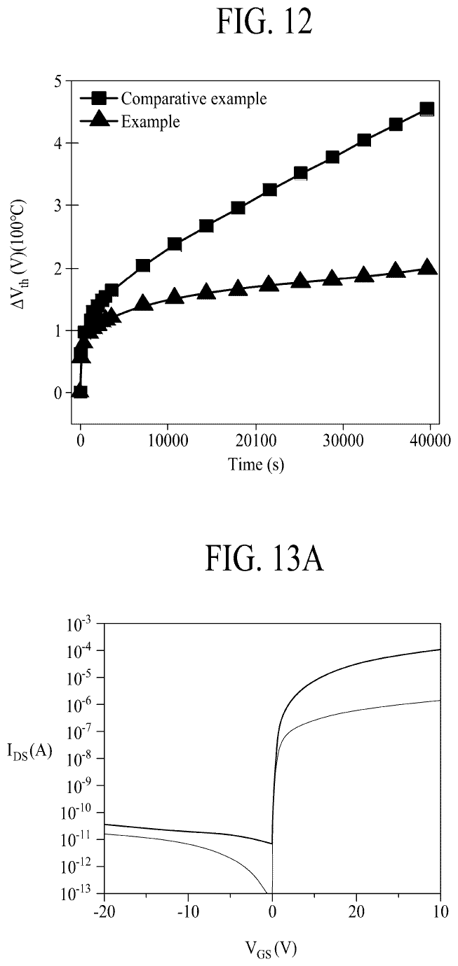

FIG. 12 shows graphs illustrating changes in threshold voltage (Vth) of thin film transistors according to an example and a comparative example under a PBTS (Positive Bias Temperature Stress) condition.

The graphs in FIG. 12 shows the results of measuring the change in threshold voltage (ΔVth) of the thin film transistors according to time (seconds, s) under the conditions in which a high temperature stress of 100° C. was applied to the thin film transistors according to an example and a comparative example.

In FIG. 12, the thin film transistor according to an example of the present disclosure comprises a main channel layer 210 and a carrier control layer 220 including an IGZO (InGaZnO) oxide semiconductor material and bismuth (Bi) doped into the IGZO (InGaZnO) oxide semiconductor material. The thin film transistor according to an example of the present disclosure has a structure shown in FIG. 1.

In FIG. 12, the thin film transistor according to the comparative example has the same structure as the example, but does not include the carrier control layer 220.

Referring to FIG. 12, in the thin film transistor according to the comparative example that does not include the carrier control layer 220, the threshold voltage (Vth) continues to increase as time (seconds, s) elapses under a temperature condition of 100° C. It can be confirmed that the threshold voltage change (ΔVth) over time is relatively large in the thin film transistor according to the comparative example compared to the thin film transistor according to the example.

In the thin film transistor according to the example, it can be confirmed that the change in threshold voltage (ΔVth) over time (seconds, s) is not large even under a temperature condition of 100° C. In particular, it can be confirmed that the thin film transistor according to the example has a relatively small threshold voltage change (ΔVth) over time compared to the thin film transistor according the comparative example.

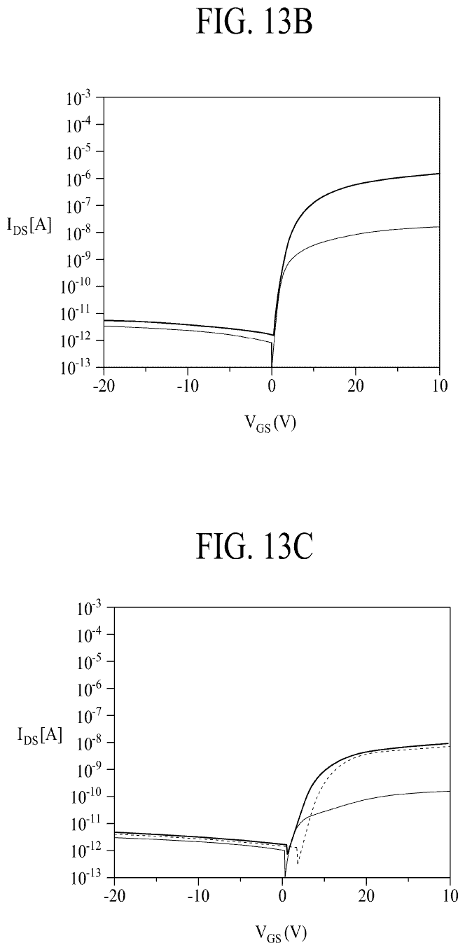

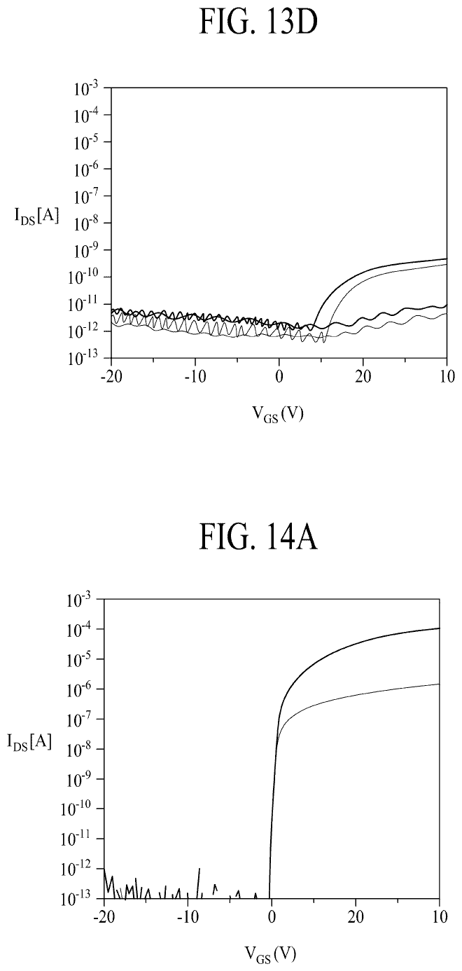

FIGS. 13A to 13D are graphs of voltage-current changes of a thin film transistor according to the thickness of the carrier control layer 220.

In the graphs of FIGS. 13A to 13D, measurements were made on a thin film transistor including a main channel layer 210 comprising an IGZO (InGaZnO) oxide semiconductor layer and a carrier control layer 220 made by an IGZO (InGaZnO) oxide semiconductor material doped with bismuth (Bi).

FIG. 13A is a voltage-current change graph measured for a thin film transistor having a carrier control layer 220 with a thickness of 1 nm. FIG. 13B is a voltage-current change graph measured for a thin film transistor having a carrier control layer 220 with a thickness of 3 nm. FIG. 13C is a voltage-current change graph measured for a thin film transistor having a carrier control layer 220 with a thickness of 5 nm. FIG. 13D is a voltage-current change graph measured for a thin film transistor having a carrier control layer 220 with a thickness of 10 nm.

Referring to FIGS. 13A to 13D, it can be shown that the thin film transistor has effective switching characteristics when the thickness of the carrier control layer 220 is 1 to 5 nm. In addition, when the thickness of the carrier control layer 220 is 1 to 5 nm, even though high temperature stress is applied, the change in the threshold voltage (Vth) of the thin film transistor over time (seconds, s) is not significant.

When the thickness of the carrier control layer 220 is less than 1 nm, the gap state formation effect by the carrier control layer 220 is not significant, and thus, the effect of maintaining the driving stability of the thin film transistor may not be significant under a condition where high temperature stress is applied. On the other hand, when the thickness of the carrier control layer 220 is more than 5 nm, due to an increase in the gap state, electrons other than those excited state are trapped in the initial state, and carriers are reduced, and as a result, the mobility and current of the thin film transistor may be reduced.

Therefore, according to an embodiment of the present disclosure, the carrier control layer 220 may be designed to have a thickness ranging from 1 to 5 nm. In detail, the carrier control layer 220 may have a thickness ranging from 1 to 3 nm.

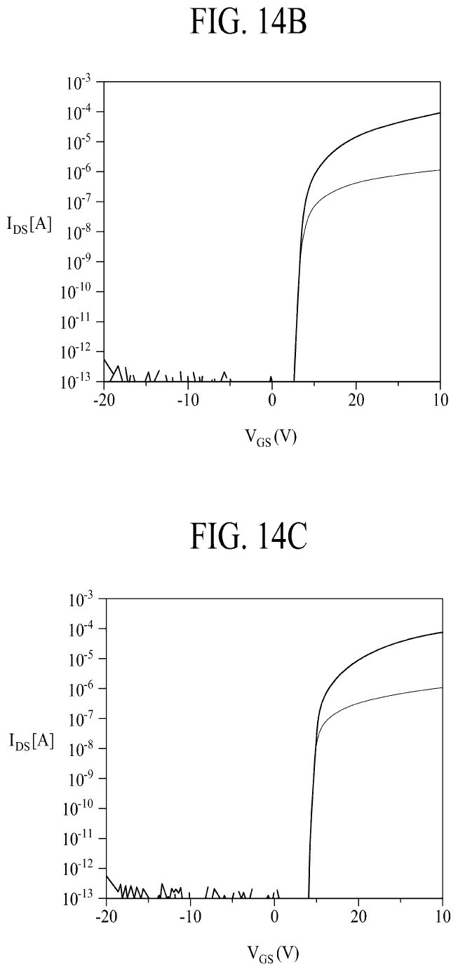

FIGS. 14A to 14C are voltage-current change graphs of thin film transistors according to the type of the element of group 15 of periodic table.

In detail, FIG. 14A is a voltage-current change graph measured for a thin film transistor having the same structure as the thin film transistor applied in FIG. 13A, in which the element of group 15 of periodic table included in the carrier control layer 220 is bismuth (Bi). Referring to FIG. 14A, it can be seen that the threshold voltage of the thin film transistor using bismuth (Bi) as the element of group 15 of periodic table is close to 0V. In addition, even though the thin film transistor is exposed to a high temperature condition for a long time, change of the threshold voltage (ΔVth) is not significant.

FIG. 14B is a voltage-current change graph measured for a thin film transistor having the same structure as the thin film transistor applied in FIG. 13A, in which the element of group 15 of periodic table included in the carrier control layer 220 is arsenic (As). Referring to FIG. 14B, it is shown that the threshold voltage of a thin film transistor using arsenic (As) as the element of group 15 of periodic table is close to 2.5V. In addition, even though the thin film transistor is exposed to a high temperature condition for a long time, change of the threshold voltage (ΔVth) is not significant.

FIG. 14C is a voltage-current change graph measured for a thin film transistor having the same structure as the thin film transistor applied in FIG. 13A, in which the element of group 15 of periodic table included in the carrier control layer 220 is phosphorus (P). Referring to FIG. 14C, it is shown that the threshold voltage of a thin film transistor using phosphorus (P) as the element of group 15 of periodic table is close to 4.5V. In addition, even though the thin film transistor is exposed to a high temperature condition for a long time, change of the threshold voltage (ΔVth) is not significant.

Referring to FIGS. 14A to 14C, it can be seen that, as the atomic weight of the element of group 15 of periodic table included in the carrier control layer 220 decreases, the depth of the gap state becomes deeper, and the threshold voltage (Vth) moves in the positive direction. When an element of group 15 of periodic table with a low atomic weight is used in the carrier control layer 220, it can be seen that the mobility of the thin film transistor decreases and thermal stability increases. On the other hand, when an element of group 15 of periodic table with a large atomic weight is used in the carrier control layer 220, it can be seen that the decrease in mobility of the thin film transistor is suppressed.

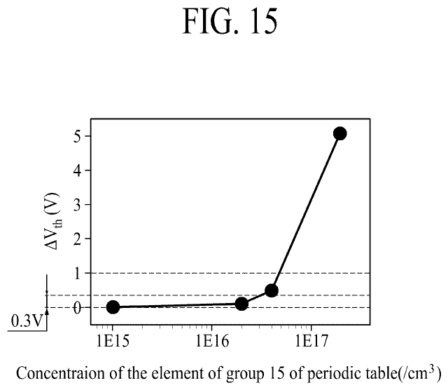

FIG. 15 is a graph of the change in threshold voltage (Vth) of a thin film transistor according to the concentration of the element of group 15 of periodic table, in a heated state of 100° C.

Referring to FIG. 15, it can be seen that, when the concentration of the element of group 15 of periodic table included in the carrier control layer 220 is 1×10¹⁵/cm³ to 1×10¹⁷/cm³, the change of the threshold voltage (ΔVth) in the thin film transistor can be maintained below about 1V, under a condition of high temperature of 100° C.

Therefore, according to an embodiment of the present disclosure, the concentration of the element of group 15 of periodic table included in the carrier control layer 220 may be adjusted to be in a range of 1×10¹⁵/cm³ to 1×10¹⁷/cm³.

When the concentration of the element of group 15 of periodic table included in the carrier control layer 220 is less than 1×10¹⁵/cm³, the gap state formation effect by the carrier control layer 220 is not significant, so that under a condition where a high temperature stress is applied, the effect of securing the driving stability of the thin film transistor may not be significant. On the other hand, when the concentration of the element of group 15 of periodic table included in the carrier control layer 220 is more than 1×10¹⁷/cm³, the change of the threshold voltage (ΔVth) in thin film transistor may increase under a condition where high temperature stress is applied, and thus driving stability of the thin film transistor may deteriorate.

Hereinafter, a display apparatus including the thin film transistor described above will be described in detail.

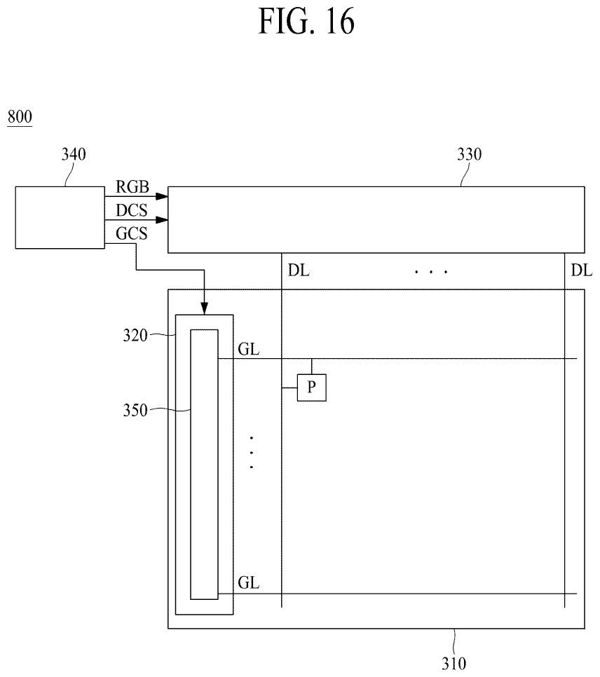

FIG. 16 is a schematic diagram of a display apparatus 800 according to another embodiment of the present disclosure.

The display apparatus 800 according to another embodiment of the present disclosure may include a display panel 310, a gate driver 320, a data driver 330, and a controller 340.

Gate lines GL and data lines DL are placed in the display panel 310, and pixels P are disposed at intersections of the gate lines GL and data lines DL. Images are displayed by driving pixels P.

The controller 340 controls the gate driver 320 and data driver 330.

The controller 340 uses, for example, a signal supplied from an external system (not shown) to generate a gate control signal GCS to control the gate driver 320 and a data control signal DCS to control the data driver 330. In addition, the controller 340 samples input image data input from an external system, realigns it, and supplies the realigned digital image data RGB to the data driver 330.

The gate control signal GCS includes a gate start pulse GSP, gate shift clock GSC, gate output enable signal GOE, start signal Vst, and gate clock GCLK. In addition, the gate control signal GCS may include control signals for controlling the shift register 350.

The data control signal DCS includes a source start pulse SSP, source shift clock signal SSC, source output enable signal SOE, and polarity control signal POL.

The data driver 330 supplies data voltage to the data lines DL of the display panel 310. In detail, the data driver 330 converts the image data RGB input from the controller 340 into an analog data voltage and supplies the data voltage to the data lines DL.

The gate driver 320 may include a shift register 350. The shift register 350 sequentially supplies gate pulses to the gate lines GL for one frame using a start signal and gate clock transmitted from the controller 340.

Using the shift register 350, the gate driver 320 can sequentially supply gate pulses GP to the gate lines GL during one frame. Here, one frame refers to the period during which one image is output through the display panel. In addition, the gate driver 320 supplies a gate off signal Goff that can turn off the switching element to the gate line GL during the remaining period in one frame in which the gate pulse GP is not supplied. Hereinafter, the gate pulse GP and the gate off signal Goff are collectively referred to as the scan signal SS.

According to an embodiment of the present disclosure, the gate driver 320 may be mounted in the display panel 310. In this way, the structure in which the gate driver 320 is directly mounted in the display panel 310 is called a gate in panel (GIP) structure.

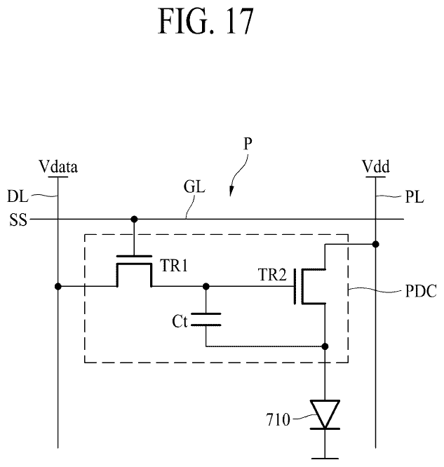

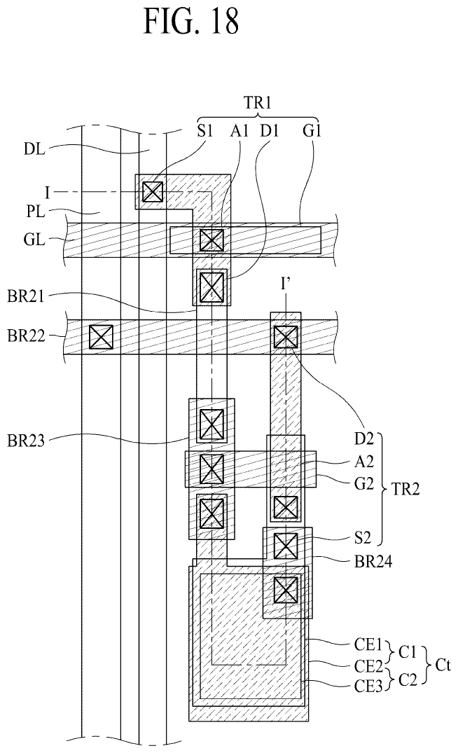

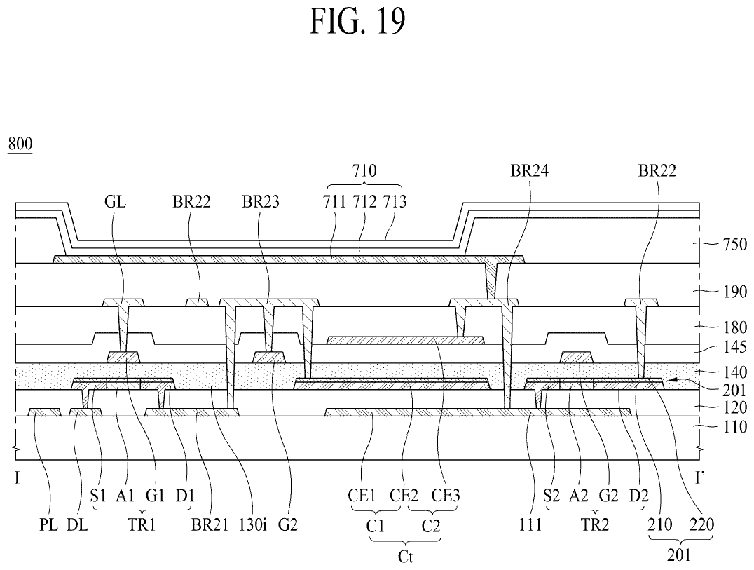

FIG. 17 is a circuit diagram of a pixel P of FIG. 16, FIG. 18 is a plan view of the pixel P of FIG. 17, and FIG. 19 is a cross-sectional view along I-I′ of FIG. 18.

The circuit diagram of FIG. 17 is an equivalent circuit diagram of a pixel P of the display apparatus 800 including an organic light emitting diode OLED as a display element 710.

The pixel P includes a display element 710 and a pixel driving circuit PDC that drives the display element 710.

The first thin film transistor TR1 is connected to the gate line GL and the data line DL, and is turned on or turned off by the scan signal SS supplied through the gate line GL.

The data line DL provides a data voltage Vdata to the pixel driving circuit PDC, and the first thin film transistor TR1 controls the application of the data voltage Vdata.

The driving power line PL provides a driving voltage Vdd to the display element 710, and the second thin film transistor TR2 controls the driving voltage Vdd. The driving voltage Vdd is a pixel driving voltage for driving the organic light emitting diode OLED, which is the display element 710.

The thin film transistors 100, 200, 300, 400, 500, 600, and 700 described above may be applied as the first thin film transistor TR1 or the second thin film transistor TR2 of FIG. 17.

When the first thin film transistor TR1 is turned on by the scan signal SS applied from the gate driver 320 through the gate line GL, the data voltage Vdata supplied from the data line DL is supplied to the gate electrode of the second thin film transistor TR2 connected to the display element 710. The data voltage Vdata is charged in the capacitor Ct formed between the gate electrode and the source electrode of the second thin film transistor TR2. The capacitor Ct of FIG. 17 is a storage capacitor.

The amount of current supplied to the organic light emitting diode OLED, which is the display element 710, through the second thin film transistor TR2 is controlled according to the data voltage Vdata, whereby a gray scale of light emitted from the display element 710 may be controlled.

Referring to FIGS. 18 and 19, the first thin film transistor TR1 and the second thin film transistor TR2 are disposed on the substrate 110.

The substrate 110 may be made of glass or plastic. As the substrate 110, a plastic with flexible properties, for example, polyimide (PI), may be used.

A light shielding layer 111 is disposed on the substrate 110. The light shielding layer 111 may have light blocking properties. The light shielding layer 111 may protect the active material layer and channel portion A2 by blocking light incident from the outside. A portion of the light shielding layer 111 may become a first capacitor electrode CE1. Referring to FIGS. 18 and 19, the light shielding layer 111 and the first capacitor electrode CEI can be formed integrally as one body.

In addition, a data line DL, a driving power line PL, and a first bridge electrode BR21 may be disposed on the substrate 110.

A buffer layer 120 is disposed on the light shielding layer 111, the first capacitor electrode CE1, the data line DL, the driving power line PL, and the first bridge electrode BR21. The buffer layer 120 may be made of an insulating material and protects the channel portions A1 and A2 from moisture or oxygen incident from the outside.

The active layer 201 is disposed on the buffer layer 120. The active layer 201 may include an oxide semiconductor material. The active layer 201 may include an oxide semiconductor layer made of an oxide semiconductor material. The active layer 201 includes a main active layer 210 and a carrier control layer 220 in contact with the main active layer 210.

The active layer 201 includes a first channel portion A1, a first source connection portion, a first drain connection portion, a second channel portion A2, a second source connection portion, and a second drain connection portion. Referring to FIGS. 18 and 19, the first source connection may become the first source electrode S1, the first drain connection may become the first drain electrode D1, the second source connection may become the second source electrode S2, and the second drain connection may become the second drain electrode D2.

In addition, a portion of the active layer 201 may be conductorized to be a second capacitor electrode CE2.

The first source electrode S1 of the first thin film transistor TR1 is connected to the data line DL through a contact hole. The first drain electrode D1 of the first thin film transistor TR1 is connected to the first bridge electrode BR21 through a contact hole.

The second source electrode S2 of the second thin film transistor TR2 is connected to the light shielding layer 111 through a contact hole. Accordingly, the same voltage as that of the second source electrode S2 may be applied to the first capacitor electrode CE1 formed integrally with the light shielding layer 111.

A gate insulating layer 140 is disposed on the active layer 201 and the second capacitor electrode CE2. The gate insulating layer 140 has insulating properties and separates the active layer 201 from the gate electrodes G1 and G2. The gate insulating layer 140 may cover the entire upper surface of the active layer 201.

The first gate electrode G1 of the first thin film transistor TR1 and the second gate electrode G2 of the second thin film transistor TR2 are disposed on the gate insulating layer 140.

Referring to FIGS. 18 and 19, an interlayer insulating film 145 may be disposed on the gate electrodes G1 and G2, and a third capacitor electrode CE3 may be disposed on the interlayer insulating film 145. The third capacitor electrode CE3 overlaps the first capacitor C1 and the second capacitor C2.

A passivation layer 180 may be disposed on the third capacitor electrode CE3. The passivation layer 180 protects the thin film transistors TR1 and TR2.

On the passivation layer 180, the gate line GL and bridge electrodes BR22, BR23, and BR24 are disposed.

The gate line (GL) is connected to the first gate electrode G1 of the first thin film transistor TR1 through a contact hole. Accordingly, the scan signal SS may be applied to the first gate electrode G1 of the first thin film transistor TR1.

The second bridge electrode BR22 is disposed on the passivation layer 180, and connects the driving power line PL and the second drain electrode D2 of the second thin film transistor TR2. Referring to FIG. 18, one side of the second bridge electrode BR22 is connected to the driving power line PL through a contact hole. The other side of the second bridge electrode BR22 is connected to the second drain electrode D2 of the second thin film transistor TR2 through a contact hole. Accordingly, the driving voltage Vdd can be applied to the second drain electrode D2 of the second thin film transistor TR2.

The third bridge electrode BR23 is disposed on the passivation layer 180, and connects the first bridge electrode BR21, the second gate electrode G2 of the second thin film transistor TR2, and the second capacitor electrode CE2 each other.

The first bridge BR21 is connected to the first drain electrode D1 of the first of thin film transistor, thus, the data voltage Vdata transmitted to the first drain electrode D1 through the first thin film transistor TR1 can be applied to the second gate electrode G2 of second thin film transistor TR2 through the first bridge BR21 and the third bridge electrode BR23.

In addition, by the third bridge electrode BR23, a same voltage as that of the second gate electrode G2 may be applied to the second capacitor electrode CE2.

As a result, a same voltage may be applied to the first drain electrode D1 of the first of thin film transistor TR1, the second gate electrode G2 of the second thin film transistor TR2, and the second capacitor electrode CE2.

The fourth bridge electrode BR24 is disposed on the passivation layer 180 to connect the light shielding layer 111 and the third capacitor electrode CE3. As a result, a same voltage as that of the first capacitor electrode CE1 may be applied to the third capacitor electrode CE3. Referring to FIGS. 18 and 19, a same voltage may be applied to the third capacitor electrode CE3 and the second source electrode S2 of the second thin film transistor TR2.

The first capacitor C1 may be formed by overlapping the first capacitor electrode CE1 and the second capacitor electrode CE2. The second capacitor C2 may be formed by overlapping the second capacitor electrode CE2 and the third capacitor electrode CE3. The entire capacitor Ct is formed by the first capacitor C1 and the second capacitor C2.

A planarization layer 190 is disposed on the gate line GL and the bridge electrodes BR22, BR23, BR24. The planarization layer 190 planarizes the upper portions of the first thin film transistor TR1 and the second thin film transistor TR2, and protects the first thin film transistor TR1 and the second thin film transistor TR2.

A first electrode 711 of the display element 710 is disposed on the planarization layer 190. The first electrode 711 of the display element 710 may contact the fourth bridge electrode BR24 through a contact hole formed in the planarization layer 190. As a result, the first electrode 711 may be connected to the second source electrode S2 of the second thin film transistor TR2.

A bank layer 750 is disposed at the edge of the first electrode 711. The bank layer 750 defines the light-emitting area of the display element 710.

An organic light emission layer 712 is disposed on the first electrode 711, and a second electrode 713 is disposed on the organic light emission layer 712. Accordingly, the display element 710 is completed. The display element 710 shown in FIG. 19 is an organic light emitting diode (OLED). Accordingly, the display apparatus 100 according to another embodiment of the present disclosure is an organic light emitting display apparatus.

In FIGS. 17 to 19, a 2TR1C structure in which the pixel driving circuit PDC has two transistors and one capacitor is described. However, another embodiment of the present disclosure is not limited thereto. The pixel driving circuit PDC according to another embodiment of the present disclosure may be formed in various structures other than those described above. The pixel driving circuit PDC may include, for example, three or more thin film transistors, and may include, for example, two or more capacitors.

The present disclosure described above is not limited to the above-described embodiments and the accompanying drawings, and it is well known to those with ordinary knowledge that various substitutions, modifications, and changes are possible within the scope of the technical details of the present disclosure.

The various embodiments described above can be combined to provide further embodiments. Aspects of the embodiments can be modified, if necessary to employ concepts of the various embodiments to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A thin film transistor comprising:
an active layer on a substrate; and
a gate electrode spaced apart from the active layer and overlapping at least a part of the active layer,
wherein the active layer comprises:
a main active layer including an oxide semiconductor layer; and
a carrier control layer contacting the main active layer,
wherein the carrier control layer comprises:
an oxide semiconductor material; and
an element of group 15 of periodic table.

2. The thin film transistor according to claim 1, wherein the element of group 15 of periodic table comprises at least one of phosphorus (P), arsenic (As), antimony (Sb), or bismuth (Bi).

3. The thin film transistor according to claim 1, wherein the oxide semiconductor material comprises at least one of an IGZO (InGaZnO)-based, an IGZTO (InGaZnSnO)-based, an IZO (InZnO)-based, an IGO (InGaO)-based, an ITO (InSnO)-based, an ITZO (InSnZnO)-based, an InO (InO)-based, a ZnO-based, an IWZO (InWZnO)-based, or a FIZO (FeInZnO)-based oxide semiconductor material.

4. The thin film transistor according to claim 1, wherein the carrier control layer has a thickness ranging from 1 to 5 nm, inclusive.

5. The thin film transistor according to claim 1, wherein the element of group 15 of periodic table has a concentration ranging from 1×10¹⁵/cm³ to 1×10¹⁷/cm³, inclusive, in the carrier control layer.

6. The thin film transistor according to claim 1, wherein the carrier control layer is configured to trap excited electrons.

7. The thin film transistor according to claim 1, wherein the carrier control layer has a thickness smaller than a thickness of the main active layer, and
the carrier control layer is disposed closer to the gate electrode than the main active layer.

8. The thin film transistor according to claim 1, wherein the carrier control layer has a thickness smaller than a thickness of the main active layer, and
wherein the carrier control layer is disposed farther from the gate electrode than the main active layer.

9. The thin film transistor according to claim 1, wherein the carrier control layer includes a first carrier control layer and a second carrier control layer,
the first carrier control layer and the second carrier control layer each have a thickness smaller than a thickness of the main active layer, and
the main active layer is disposed between the first carrier control layer and the second carrier control layer.

10. The thin film transistor according to claim 1, wherein the main active layer comprises:
a first oxide semiconductor layer; and
a second oxide semiconductor layer on the first oxide semiconductor layer,
wherein the second oxide semiconductor layer has a higher carrier concentration than a carrier concentration of the first oxide semiconductor layer, and
the second oxide semiconductor layer contacts the carrier control layer.

11. The thin film transistor according to claim 1, wherein the active layer comprises:
a channel portion overlapping the gate electrode;
a source connection portion connected to a first side of the channel portion; and
a drain connection portion connected to a second side of the channel portion, and
wherein each of the source connection portion and the drain connection portion comprises:
an element of group 15 of periodic table; and
at least one of boron (B), fluorine (F), or hydrogen (H).

12. The thin film transistor according to claim 1, wherein the active layer is disposed between the substrate and the gate electrode.

13. The thin film transistor according to claim 1, wherein the gate electrode is disposed between the substrate and the active layer.

14. A display apparatus comprising:
a thin film transistor of claim 1; and
a light emitting element.
